(19) United States
(12) Patent Application Publication
(10) Pub. No.: US 2009/0274381 A1
(43) Pub. Date: Nov. 5, 2009

(54) SCALABLE CODING

(75) Inventor: Ihor Olehovych Kirenko, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/722,029

(22) PCT Filed: Dec. 16, 2005
(86) PCT No.: PCT/IB05/54280

§ 371 Date: Jun. 18, 2007

(30) Foreign Application Priority Data
Dec. 22, 2004 (EP) 04106895.8

(51) Int. Cl. G06K 9/36; G06K 9/46; H03M 7/00

(52) U.S. Cl. 382/236; 382/239; 341/59

(57) ABSTRACT

A method of encoding data comprises the steps of dividing the data into sets of data, transforming each set of data into a set of transform coefficients (A, B, C), assigning each transform coefficient to a single sub-set (S0, S1, . . . ) of the respective set of transform coefficients in dependence of its magnitude, and encoding each sub-set separately. The method may include the step of comparing the magnitudes of the transform coefficients of each set with at least one threshold value (T1, T2, . . . ). As each sub-set contains the entire magnitude of selected transform coefficients, the loss of another sub-set during transmission has no effect on these transform coefficients. The method is particularly suitable for encoding picture data.

The present invention relates to scalable coding. More in particular, the present invention relates to a method and a device for encoding data, which method and device produce at least two layers of encoded information. A first layer contains basic encoded information which allows a relatively coarse (that is, low resolution and/or low quality) reconstruction of the original data, while at least one second layer contains additional encoded information which allows, in combination with the first layer, a relatively fine (that is, high resolution and/or high quality) reconstruction of the original data.

Scalable coding is widely used in video coding. In the well-known MPEG standards, the first layer is called “base layer” (BL) while the second layer is referred to as “enhancement layer” (EL). Both layers may be produced by transforming blocks of picture data and then encoding the resulting blocks of transform coefficients by scanning and variable length encoding. The “base layer” is typically a down sampled version of the “enhancement layer”.

Alternative techniques of producing multiple layers may be used. For example, the transform coefficients may be divided into so-called bit planes, each bit plane containing one or more bits of each transform coefficient of a block. The bit planes may be assigned to different layers, such the “base layer” and one or more “enhancement layers”. The number of bit-planes transmitted and received determines the resolution of the reconstructed image. This type of scalability is referred to as Fine Grain Scalability (FGS).

U.S. Pat. No.6,501,397 (Radha et al./Philips) discloses a method of image signal compression and encoding involving bit-plane encoding. By combining two or more bit-planes, the coding efficiency may be improved. The entire contents of U.S. Pat. No. 6,501,397 are herewith incorporated in this document.

Splitting the transform coefficients into bit-planes has the disadvantage that each bit-planes contains only partial information on each transform coefficient. If some bit-planes are lost during transmission, the missing bits result in an incorrect representation of the transform coefficients and therefore in distorted reconstructed data (such as image data). If only a single bit plane is received, the partial information contained in the bit-plane will generally be insufficient to reconstruct the original data in a meaningful way.

It is an object of the present invention to overcome these and other problems of the Prior Art and to provide a method and device for encoding data which is more resilient to transmission losses yet is simple to implement.

Accordingly, the present invention provides a method of encoding sets of data, the method comprising the steps of:

transforming each set of data into a set of transform coefficients,

assigning each transform coefficient to a single sub-set of the respective set of transform coefficients dependent on its magnitude, and

encoding each sub-set separately.

By assigning transform coefficients to sub-sets dependent on the magnitude of the transform coefficients, an efficient splitting of transform coefficients into different sub-sets is achieved, while different sub-sets may be used to produce different encoding layers. The number of sub-sets may vary and two, three, four, five or more sub-sets may be used.

By assigning each transform coefficient to a single sub-set, each sub-set contains the entire value (that is, all bits) of one or more transform coefficients (unless no transform coefficient exceeded the respective threshold value, leaving the sub-set empty). As a result, each sub-set received after transmission allows some transform coefficients to be fully known, thus avoiding any distortion of the original data. Of course the loss of a sub-set during transmission may result in some transform coefficients being lost, which may introduce some distortion of the reconstructed data, but in contrast to bit-plane coding, the loss of a single sub-set does not result in a distortion of all transform coefficients.

By encoding each sub-set separately, that is, by encoding the transform coefficients per sub-set, the coding can be simple and efficient. In addition, the present invention offers the significant advantage that one particular sub-set will contain the most relevant transform coefficients, that is, the transform coefficients having the greatest magnitudes. If the bandwidth of the transmission channel is limited, transmitting this single sub-set (preferably as “base layer”) will result in the best approximation of the original data.

It will be understood that if the data are provided as an undivided stream, the method may include the further step of dividing the data into sets of data.

Assigning the transform coefficients to sub-sets on the basis of their magnitudes (amplitudes) may be achieved in various ways, for example by using a look-up table, each entry in the table representing a magnitude and its corresponding sub-set. However, it is preferred to compare the magnitude of each transform coefficient with at least one threshold value to select the sub-set the transform coefficient is assigned to.

By comparing the magnitudes of the transform coefficients of each set with at least one threshold value, it is possible to efficiently group the transform coefficients according to their respective magnitudes. Each transform coefficient may then be assigned to a single sub-set of the respective set of transform coefficients dependent on the comparison.

A preferred embodiment comprises the further step of subtracting the respective threshold value from each transform coefficient prior to the step of encoding each sub-set separately. This decreases the magnitudes of the transform coefficients and allows a more efficient encoding.

Although a single threshold value may be used, effectively splitting each set of transform coefficients into two sub-sets, it is preferred that two or more threshold values are used, thus creating multiple sub-sets of each set of transform coefficients. For example, four threshold values may be used, resulting in five sub-sets. The threshold values may be evenly spaced (for example 2, 4, 6, and 8 if the maximum transform coefficient value is 10), but may also be unequally spaced (for example 3.6, 4.9, 6.4 and 8.1 if the maximum transform coefficient value is 10).

In a further embodiment, the threshold values may be dynamically adjusted, for example so as to evenly distribute the transform coefficients over the relevant sub-sets. In such an embodiment, it is preferred that the threshold values are also transmitted to allow a correct reconstruction at the receiving side. In embodiments in which the threshold values are static (that is, substantially fixed), they need not be transmitted.

The method may also involve the step of scaling the transform coefficients, preferably after comparing their magnitudes with the threshold values. Alternatively, the threshold values may be scaled.

In a preferred embodiment, the method according to the present invention comprises the further step of combining the encoded transform coefficients of each sub-set into a single stream of encoded transform coefficients. Advantageously, the at least one threshold value may be combined with the encoded transform coefficients. In case look-up tables are used instead of, or in addition to thresholds, table identifiers may be combined with the encoded transform coefficients. In this way each stream contains both transform coefficients and data identifying and/or defining the respective sub-set.

The step of encoding each sub-set may advantageously involve variable length coding (VLC), and the step of transforming may involve a digital cosine transform (DCT) or a digital wavelet transform (DWT).

Although various types of data may be used, the method of the present invention is particularly advantageous when the data are picture (still picture or image, and/or moving picture or video) data.

The present invention further provides a computer program product for encoding sets of data, the computer program product comprising computer executable instructions for carrying out the steps of:

transforming each set of data into a set of transform coefficients,

assigning each transform coefficient to a single sub-set of the respective set of transform coefficients in dependence on its magnitude, and

encoding each sub-set separately.

The computer program product may comprise additional computer executable instructions, for example instructions for comparing the magnitudes of the transform coefficients of each set with at least one threshold value. The computer program product may comprise a carrier, such as a CD or DVD, on which the program is stored. Alternatively, the computer program product may be stored on a remote server and may be downloaded using the Internet.

The present invention also provides a device for encoding sets of data, the device comprising:

transform means for transforming each set of data into a set of transform coefficients,

assignment means for assigning each transform coefficient to a single sub-set of the respective set of transform coefficients in dependence on its magnitude, and

encoding means for encoding each sub-set separately.

The encoding device may further comprise comparison means for comparing the magnitudes of the transform coefficients of each set with at least one threshold value, and/or motion estimation means for deriving motion vectors.

In addition, the present invention provides a device for transcoding sets of data, the device comprising:

decoding means for decoding sets of data,

assignment means for assigning each transform coefficient to a single sub-set of the respective set of transform coefficients in dependence on its magnitude, and

encoding means for encoding each sub-set separately.

Such a transcoding device may be used to transform a set of conventionally encoded data into a set of data encoded in accordance with the present invention. The transcoding device may further comprise comparison means for comparing the magnitudes of the transform coefficients of each set with at least one threshold value, and/or inverse transform means arranged for inversely transforming sets of data and transform means for transforming each set of data into a set of transform coefficients, and/or inverse quantization means for inversely quantizing decoded sets of data. Motion compensation means may also be provided.

The present invention further provides a decoding device for decoding sets of data encoded by the encoding device as defined above or the transcoding device as defined above, the device comprising:

decoding means for decoding sub-sets of data,

grouping means for grouping decoded sub-sets of data into sets of transform coefficients,

inverse transform means for inversely transforming sets of transform coefficients.

The decoding device may further comprise inverse scanning means for inversely scanning sets of transform coefficients, and/or motion compensation means for providing motion compensation.

The present invention further provides a portable consumer device, such as a video camera, comprising an encoding device as defined above. Other examples of portable consumer devices the present invention may provide are digital (still) cameras, cellular (mobile) telephones, PDAs (Personal Digital Assistants), and portable television apparatus.

The present invention additionally provides a video transmission system, comprising an encoding device as defined above and/or a transcoding device as defined above and/or a decoding device as defined above.

The algorithmic components disclosed in this document may in practice be (entirely or in part) realized as hardware (e.g. parts of an application specific IC) or as software running on a special digital signal processor, or a generic processor, etc. Under computer program product should be understood any physical realization of a collection of commands enabling a (generic or special purpose) processor, after a series of loading steps (which may include intermediate conversion steps, like translation to an intermediate language, and a final processor language) to get the commands into the processor, to execute any of the characteristic functions of an invention. In particular, the computer program product may be realized as data on a carrier such as e.g. a disk or tape, data present in a memory, data traveling over a (wired or wireless) network connection, or program code on paper. Apart from program code, characteristic data required for the program may also be embodied as a computer program product. Some of the steps required for the working of the method may be already present in the functionality of the processor instead of described in the computer program product, such as data input and output steps.

It is noted that the present invention is not limited to image (or video) encoding and may also be used for encoding other data, for example audio data.

The present invention will further be explained below with reference to exemplary embodiments illustrated in the accompanying drawings, in which:

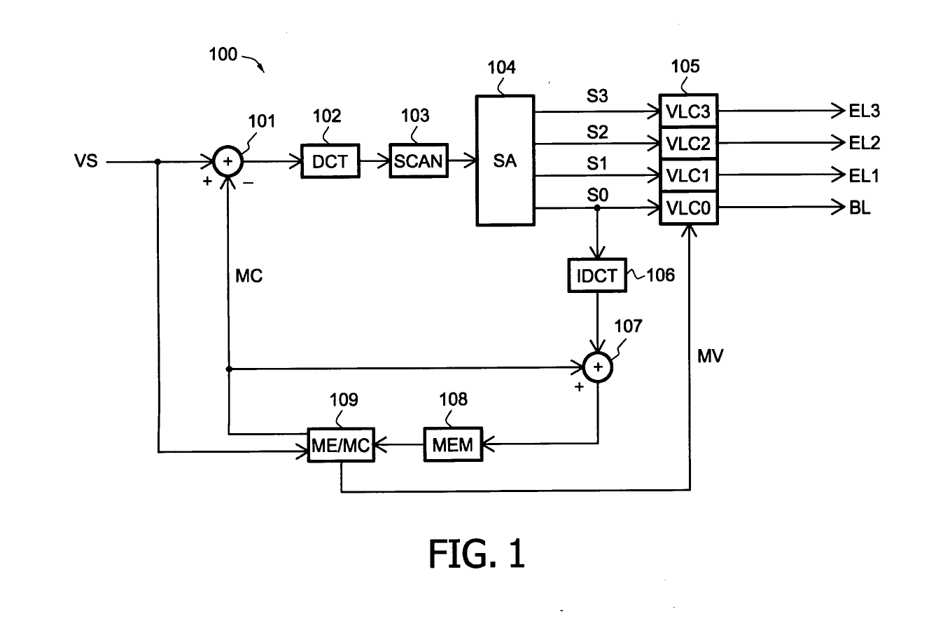

FIG. 1 schematically shows an encoding device according to the present invention.

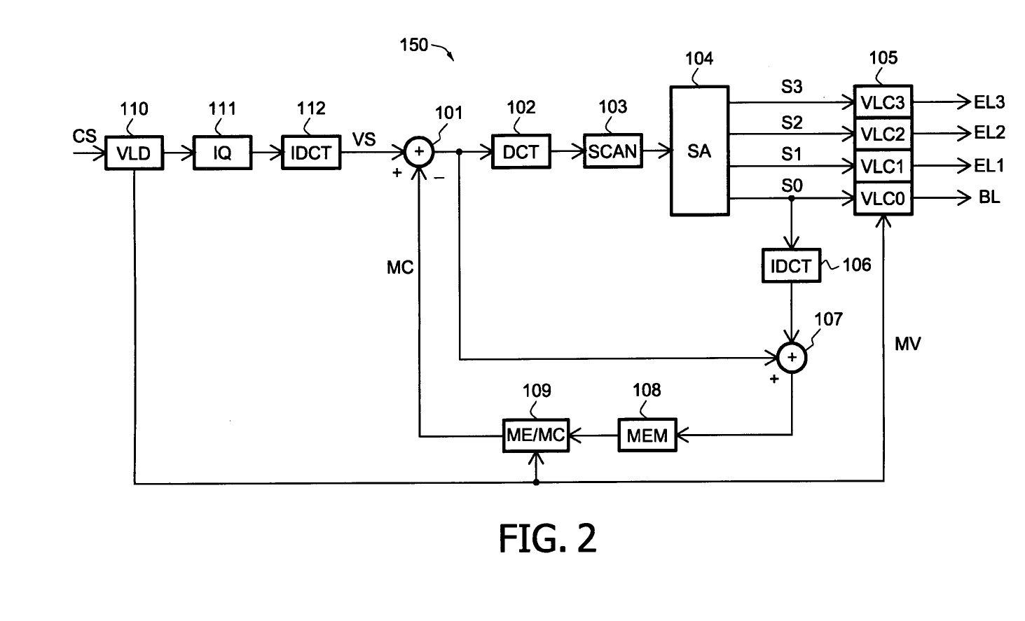

FIG. 2 schematically shows a transcoding device according to the present invention.

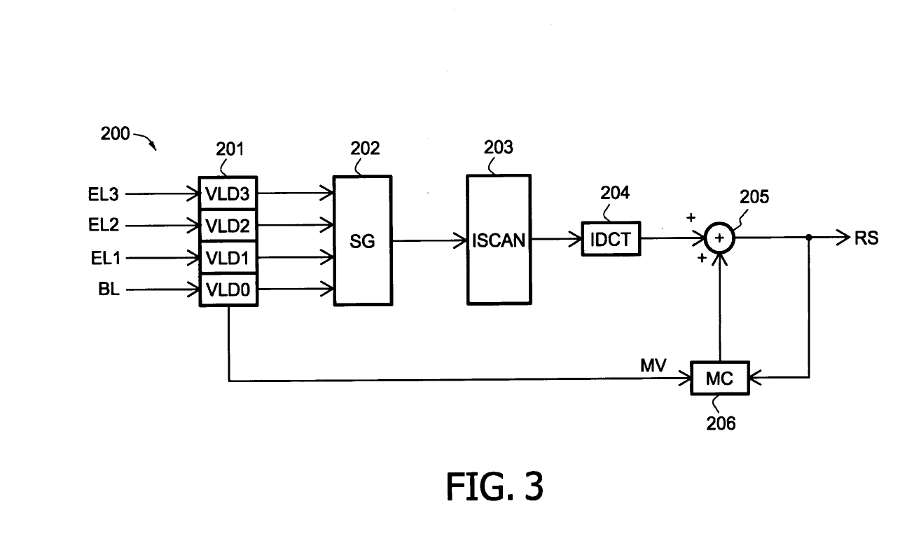

FIG. 3 schematically shows a decoding device according to the present invention.

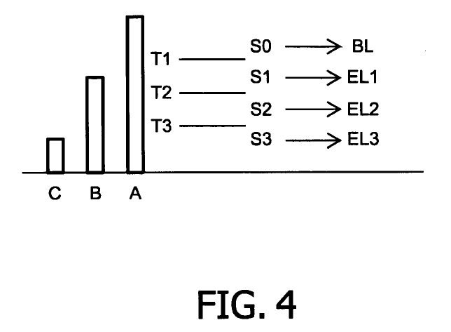

FIG. 4 schematically shows the assigning of transform coefficients to data sub-sets in accordance with the present invention.

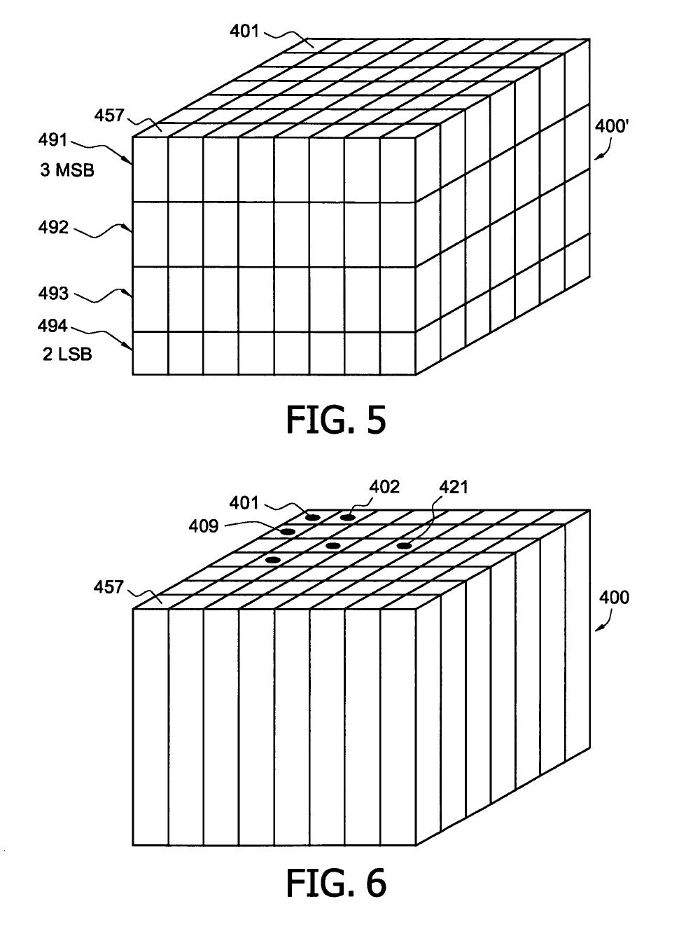

FIG. 5 schematically shows a set of transform coefficients according to the Prior Art.

FIG. 6 schematically shows a set of transform coefficients according to the present invention.

The inventive encoding device 100 shown merely by way of non-limiting example in FIG. 1 comprises a subtraction unit 101 for receiving an input signal VS. In the present example, it will be assumed that the input signal VS is a video signal consisting of sets of picture data, each set (or “block”) representing 8×8 pixels (picture elements). However, the present invention is not limited to video signals, nor to a specific data structure.

The subtraction unit 101 is arranged for subtracting a motion predicted signal MC from the input video signal VS. The resulting difference signal is fed to a transform unit 102 which transforms the sets of picture data into sets of transform coefficients. Picture data are typically transformed using the Discrete Cosine Transform (DCT), which is well known in the art, although other transforms may also be used, for example the (Digital) Wavelet Transform (DWT). The transform coefficients resulting from the DCT may be interpreted as (spatial) frequency components.

A scanning (SCAN) unit 103 scans each set of transform coefficients in a predetermined order, for example the “zig-zag” order used in MPEG compatible systems. The scanning unit 103 converts the two-dimensional set of transform coefficients output by the transform unit 102 into a one-dimensional set. Embodiments can be envisaged in which the scanning unit 103 is incorporated into the transform unit 102, in which case the transform unit 102 outputs a one-dimensional set of transform coefficients.

The sets of transform coefficients are fed to a stream assignment (SA) unit 104 which compares the individual transform coefficients of each set with one or more thresholds and subsequently assigns each transform coefficient to a corresponding sub-set or stream. In the present example, there are three thresholds and four sub-sets, each sub-set corresponding with one stream (embodiments can be envisaged in which the number of streams is smaller than the number of sub-sets, that is, where at least two sub-sets are combined into one stream). The threshold comparison will later be further explained with reference to FIG. 4.

Most, if not all sub-sets, will contain less than the maximum number of transform coefficients, for example 10 when the maximum number is 64 (e.g. a block of 8×8 coefficients). The “empty” places in each sub-set may be filled with zeroes, thus maintaining a standard sub-set size.

The stream assignment unit 104 produces four data streams S0, S1, S2, and S3, each containing a sub-set of the transform coefficients of a set of data. All data streams S0, S1, . . . are fed to a corresponding section VLC0, VLC1, . . . of an encoding unit 105. Each section of the encoding unit 105 encodes the respective data stream separately using a suitable encoding technique, in the present example Variable Length Coding (VLC), to produce an output data stream. The Base Layer stream BL is produced by the section VLC0, while the Enhancement Layer streams EL1, EL2 and EL3 are produced by the sections VLC1, VLC2 and VLC3 respectively.

Typical encoding units use a look-up table (LUT) to produce code words. Although all sections VLC0-VLC3 of the encoding unit 105 may use the same look-up table or identical tables, in advantageous embodiments different sections may use individual look-up tables so as to improve their coding efficiency. It will be understood that instead of variable length coding (VLC), other encoding techniques may be used, such as run length coding.

In the embodiment of FIG. 1, the “lowest” data stream S0 is also fed to an inverse transform unit 106 which, in the present example, carries out an Inverse Discrete Cosine Transform (IDCT). The resulting inversely transformed data stream is fed, via an adder 107, to a memory (MEM) 108 for temporary storage (delay). The delayed data are fed to a Motion Estimation/Motion Compensation (ME/MC) unit 109 which produces the motion predicted (motion compensation) signal MC and motion vectors MV using techniques that are well known to those skilled in the art. The motion vectors MV are fed to the section VLC0 of the encoding unit 105 so as to include the motion vectors in the Base Layer stream BL.

The device 100 of the present invention may further comprise a quantization unit (not shown) for data reduction. A quantization unit may be arranged between the transform unit 102 and the scanning unit 103, or between the scanning unit 103 and the stream assignment unit 104. If a quantization unit is present, the device 100 may further comprise an inverse quantization unit to estimate any discrepancies between the quantized data and the original data. As quantization results in lossy encoding, some discrepancy will typically be present.

The device 100 of FIG. 1 may be compatible with an MPEG (Motion Pictures Expert Group) standard, for example the well-known MPEG-2 standard.

A transcoder in accordance with the present invention is schematically shown in FIG. 2. The transcoder 150 is arranged for decoding a single layer (non-scalable) data stream according to the Prior Art and for encoding the decoded data stream in accordance with the present invention. The transcoder 150 of FIG. 2 comprises all components of the encoder 100 of FIG. 1 plus a variable length-decoding (VLD) unit 110, an inverse quantization (IQ) unit 111 and an inverse discrete cosine transform (IDCT) unit 112.

The variable length-decoding (VLD) unit 110 receives an encoded input signal (coded stream) CS which has been encoded using conventional variable length encoding, quantization and transformation using the discrete cosine transform (DCT). The variable length decoding (VLD) unit 110, inverse quantization (IQ) unit 111 and inverse discrete cosine transform (IDCT) unit 112 convert this coded stream into an video signal (video stream) VS which is fed to the subtracter 101 as in the encoding device 100 of FIG. 1. Motion vectors MV are output by the variable length decoding unit 110 and fed to the Motion Estimation/Motion Compensation (ME/MC) unit 109 and the encoding unit 105. It can thus be seen that the transcoder 150 is capable of receiving an input signal that has been encoded in accordance with the Prior Art, and producing an output signal that has been encoded in accordance with the present invention.

A decoder for decoding a signal (for example a video stream) is illustrated in FIG. 3. The decoder 200 comprises a decoding unit 201, a sub-set grouping (SG) unit 202, an inverse scanning (ISCAN) unit 203, an inverse discrete cosine transform (IDCT) unit 204, an adder 205 and a motion compensation (MC) unit 206.

Each section of the decoding unit 201 decodes the respective data stream separately using a suitable decoding technique, in the present example Variable Length Decoding (VLD), to produce a corresponding output data stream. The Base Layer stream BL is decoded by the section VLD0, while the Enhancement Layer streams EL1, EL2 and EL3 are decoded by the sections VLD1, VLD2 and VLD3 respectively.

The decoded streams are fed to the grouping unit 202, which groups the streams into a single stream. In accordance with the present invention, each section VLD0, VLD1, . . . of the decoding unit 201 decodes several complete transform coefficients. The transform coefficients decoded by each section form a sub-set of a total set of transform coefficients (typically 64). The grouping unit 202 reconstructs the set of transform coefficients by grouping the transform coefficients output by the different sections of the decoding unit 201. The inverse scanning unit 203 subsequently performs an inverse scanning so as to convert each one-dimensional set of transform coefficients into a two-dimensional set. It will be understood that the inverse scanning unit 203 may be incorporated into the inverse transform unit 204.

The inverse transform (IDCT) unit 204 then performs an inverse discrete cosine transform to reconstruct the original time-domain data. In an adder 205, motion compensation is carried out on the basis of motion vectors MV which the Base Layer decoding unit section VLD0 supplies to the motion compensation (MC) unit 206. The adder 205 produces the decoded output stream (reconstructed signal) RS. The output stream RS is also fed to the motion compensation unit 206.

The principle of the present invention will be further explained with reference to FIGS. 4-6. FIG. 4 illustrates how transform coefficients A, B and C are assigned to sub-sets in accordance with the present invention. It is noted that the transform coefficients A, B and C may be output by the transform unit 102 of FIG. 1.

In MPEG compatible devices, sets or “blocks” of 8×8 (picture or other) data are transformed into sets or “blocks” of 8×8 transform coefficients using a discrete cosine transform. Such blocks of transform coefficients are schematically illustrated in FIGS. 5 and 6. In the block 400′ according to the Prior Art, each of the 64 transform coefficients is split up into several parts, each parts containing several bits of the coefficient. The transform coefficient 457, for example, is shown to comprise a first part 491 consisting of the three most significant bits (MSB), a second part 492 consisting of the next three bits, a third part 493 consisting of another three bits, and a fourth part 494 consisting of the two least significant bits (LSB). As this is done for all transform coefficients of the block 400′, the block is divided into “slices” corresponding with the parts 491-494, each slice containing a few (in the present example two or three) bits of each transform coefficients. Subsequently, these slices are encoded and transmitted separately. At the receiving end, these “slices” are combined so as to reconstruct the transform coefficients.

Although this known arrangement allows a relatively efficient encoding as many of the transform parts in a slice will be equal to zero, it has disadvantages. The most serious disadvantage is the fact that if any of the slices is mutilated or lost during transmission, an accurate reconstruction of the transform coefficients has become impossible as some bits of all transform coefficients of a block are lost.

The present invention solves this problem by splitting up the blocks of transform coefficients in a different manner. The transform coefficients are not each split up into constituent parts but are assigned to different sub-sets of each block in accordance with their magnitude (amplitude). In this way, each sub-set contains the complete values (that is, all bits) of its coefficients. However, each sub-set contains the values of only a limited number of coefficients (unless all coefficients have substantially the same value, in which case they may all be assigned to the same sub-set). As a result, each block may still be split up into a number of sub-sets which may be used to produce a scalable stream while the loss of one sub-set will typically not result in all transform coefficients being affected.

A set or “block” of 8×8 transform coefficients in accordance with the present invention is schematically shown in FIG. 6. The block 400 is also constituted by 64 coefficients, which however have not been split up into several parts or slices as in FIG. 5. Instead, each coefficient as a whole is assigned to a subset. In the example of FIG. 6, the set 400 is split into two subsets. The coefficients 401, 402, 409, 419, 421 and 426 are assigned to a first subset (and are indicated by a dot in FIG. 6), while the remaining coefficients, including coefficient 457, are assigned to a second subset. It will be clear that the first subset contains the entire values of the coefficients 401, 402, 409, 419, 421 and 426, while the second subset contains the entire values of the remaining coefficients.

The mechanism of assigning the transform coefficients to the sub-sets as carried out by the assignment unit 104 in FIG. 1 will now be explained with reference to FIG. 4. Three exemplary transform coefficients A, B, and C having different magnitudes (amplitudes) are compared with thresholds T1, T2 and T3. The thresholds define levels or sub-sets, the highest threshold T1 corresponding with the stream S0 in FIG. 1, which results in the base layer stream BL after encoding. It will be understood that the streams S0 . . . S3 contain the corresponding sub-sets of each block of transform coefficients.

As coefficient A exceeds the threshold T1, it is assigned to the stream S0. Coefficient B does not exceed the first threshold T1 and is therefore compared with the second threshold T2. As it exceeds the second threshold T2, coefficient B is assigned to the stream S1 which results in the first enhancement layer EL1 after encoding. Coefficient C does not exceed any of the thresholds and is assigned to the stream S3, which results in the layer EL3.

It can thus be seen that coefficients are assigned to streams (or sub-sets) on the basis of their magnitudes. In the example of FIG. 4, the coefficients having the largest magnitudes (that is, exceeding the highest threshold T1) are assigned to the sub-set that is encoded as the base layer BL. This has the advantage that the transform coefficients having the greatest relative “weight” (that is, the greatest contribution to the reconstructed data after decoding) are encoded in the base layer, and the remaining, smaller coefficients are encoded in the enhancement layer(s). Accordingly, if an enhancement layer is lost during transmission, the impact on the decoded, reconstructed data is limited.

It will be understood that the number of thresholds is not essential to the present invention and that one, two, three, four, five or more thresholds could be used. Thresholds could be static (e.g. predetermined) or dynamic (e.g. adjustable). Embodiments can be envisaged in which the thresholds are dynamically adjusted in response to the extent to which the coefficients are distributed over the sub-sets. For example, a substantially even distribution of the coefficients over the sub-sets could be provided by suitably adjusting the thresholds. Thresholds may be adjusted to have a certain value relative to the maximum transform coefficient magnitude in a set. Thresholds may also be based upon the properties of the human eye. Non-stationary threshold values should also be transmitted and may be included in the stream S0 which results in the base layer BL.

The present invention is based upon the insight that splitting transform coefficients into constituent parts and transmitting those (encoded) parts separately increases the vulnerability to transmission errors. The present invention benefits from the insight that creating sub-sets of sets of transform coefficients on the basis of their magnitudes and transmitting the entire values of the (encoded) coefficients is an efficient transmission mechanism for scalable data, such as picture data.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

Although the present invention has been explained with reference to video (picture) data, the invention is not so limited and may also be used for encoding audio data.

It will therefore be understood by those skilled in the art that the present invention is not limited to the embodiments illustrated above and that many modifications and additions may be made without departing from the scope of the invention as defined in the appending claims.

1. A method of encoding sets of data, the method comprising the steps of:
transforming each set of data into a set of transform coefficients,
assigning each transform coefficient to a single sub-set of the respective set of transform coefficients dependent on its magnitude, and
encoding each sub-set separately.

2. The method according to claim 1, comprising the further step of comparing the magnitude of each transform coefficient with at least one threshold value to select the sub-set the transform coefficient is assigned to.

3. The method according to claim 2, comprising the further step of subtracting the respective threshold value from each transform coefficient prior to the step of encoding each sub-set separately.

4. The method according to claim 2, comprising the further step of dynamically adjusting the at least one threshold value (T1, . . . ), for example so as to evenly distribute the transform coefficients over the relevant sub-sets.

5. The method according to claim 1, comprising the further step of combining the encoded transform coefficients of each sub-set into a single stream of encoded transform coefficients.

6. The method according to claim 2, wherein the at least one threshold value (T1, . . . ) is combined with the encoded transform coefficients.

7. The method according to claim 1, wherein the step of encoding each sub-set involves variable length coding (VLC) or run length coding (RLC).

8. The method according to claim 1, wherein the step of transforming involves a digital cosine transform (DCT) or a digital wavelet transform (DWT).

9. The method according to claim 1, wherein the data are picture data.

10. A computer program product for encoding sets of data, the computer program product comprising computer executable instructions for carrying out the steps of:
transforming each set of data into a set of transform coefficients,
assigning each transform coefficient to a single sub-set of the respective set of transform coefficients in dependence on its magnitude, and
encoding each sub-set separately.

11. A device (100) for encoding sets of data, the device comprising:
transform means (102) for transforming each set of data into a set of transform coefficients,
assignment means (103) for assigning each transform coefficient to a single sub-set of the respective set of transform coefficients in dependence on its magnitude, and
encoding means (105) for encoding each sub-set separately.

12. The device according to claim 11, further comprising motion estimation means (109) for deriving motion vectors (MV).

13. The device (150) for transcoding sets of data, the device comprising:
decoding means (110) for decoding sets of data,
assignment means (103) for assigning each transform coefficient to a single sub-set of the respective set of transform coefficients in dependence on its magnitude, and
encoding means (105) for encoding each sub-set separately.

14. The device according to claim 13, further comprising inverse quantization means (111) for inversely quantizing decoded sets of data.

15. A decoding device (200) for decoding sets of data encoded by an encoding device, the decoding device comprising:
decoding means (201) for decoding sub-sets of data,
grouping means (202) for grouping decoded sub-sets of data into sets of transform coefficients, and
inverse transform means (204) for inversely transforming sets of transform coefficients.

16. The device according to claim 15, further comprising motion compensation means (206).

17. (canceled)

18. (canceled)
